(19) United States
(12) Patent Application Publication
(10) Pub. No.: US 2007/0102726 A1
(43) Pub. Date: May 10, 2007

(54) Semiconductor device for improving channel mobility

(76) Inventors: Ryota Watanabe, Kanagawa-ken (JP); Taiki Komoda, Kanagawa-ken (JP); Amane Oishi, Kanagawa-ken (JP); Yasunori Okayama, Kanagawa-ken (JP)

Correspondence Address: SPRINKLE IP LAW GROUP, 1301 W. 25TH STREET, SUITE 408, AUSTIN, TX, 78705, US

(21) Appl. No.: 11/590,060

(22) Filed: Oct. 31, 2006

(30) Foreign Application Priority Data
Oct. 31, 2005 (JP) P2005-317627

(51) Int. Cl. H01L 29/739

(52) U.S. Cl. 257/194

(57) ABSTRACT

A semiconductor device includes a substrate, a gate electrode formed on the substrate, a source region and a drain region formed in the substrate, the source region and the drain region formed located on the both side of the gate electrode, a first insulating film formed on the substrate, the first insulating film for generating a stress in a channel region under the gate electrode, a contact formed on the source region and the drain region, and the contact formed so that an amount of the first insulating film formed on the source region is larger than an amount of the first insulating film formed on the drain region.

### CROSS REFERENCE TO THE RELATED APPLICATION

This application is based upon and claims the benefit of priority from the prior Japanese Application No. 2005-317627, filed Oct. 31, 2005, the entire contents of which are incorporated herein by reference.

### FIELD OF THE INVENTION

This invention relates to semiconductor device for improving channel mobility. More particularly, the invention pertains to a semiconductor device including stress film for improving channel mobility.

### BACKGROUND OF THE INVENTION

Semiconductor devices of recent years operate at remarkably higher speeds. A background for the higher operating speeds is remarkable progress in techniques for constructing semiconductor devices in fine sizes, that is, in lithography techniques which are parts of techniques for processing semiconductor devices in fine sizes.

These days, however, technological progress in other fields requires gates to be processed with minimum dimensions which can be realized only by means of wavelengths shorter than those used in lithography. This makes it difficult to process semiconductor devices in further finer sizes.

Against this background, the following method has been proposed as a method for operating semiconductor devices at further higher speeds by use of the conventional lithography technologies. According to this proposed method, in a MOS transistor, an insulating film for imparting stress to a channel region is formed in a way that the insulating film covers a gate electrode, and thus the stress is generated in the channel region under the gate electrode. This makes it possible to improve mobility of electrons in the channel region, and to improve drain current.

Despite the proposed method, however, demand for constructing semiconductor devices in finer sizes in these years brings about a problem that, when a contact hole is made after forming the insulating film, the insulating film is etched too much so that the insulating film is left less than necessary around the gate electrode, and that no sufficient stress can be accordingly generated in the channel region. That is because the demand for constructing semiconductor devices in finer sizes requires the distances between two gate electrodes, between two contacts, and between the gate electrode and the contact to be made narrower.

To solve this problem, it is theoretically possible to widen the distance between the gate electrode and the contact. However, the wider distance between the gate electrode and the contact is undesirable because the wider distance leads to increase of the area of the cell. By contrast, it is theoretically possible that the contact is made with a smaller size, and that the area of the insulating film to be etched is thus reduced. However, if the contact is made in a smaller size, this brings about a problem that the margin of an opening to a source/drain diffusion layer is reduced when the contact hole is made.

### SUMMARY OF THE INVENTION

One or more of the problems outlined above may be addressed by embodiments of the invention. Broadly speaking, systems and methods are provided to identify the power usage characteristics of software programs and using the information to determine the manner in which the software programs will be executed, thereby improving the management of power within the device executing the programs.

A semiconductor device according to an aspect of the present invention is characterized by including a substrate, a gate electrode formed on the substrate, a source region and a drain region formed in the substrate, the source region and the drain region formed located on the both side of the gate electrode, a first insulating film formed on the substrate, the first insulating film for generating a stress in a channel region under the gate electrode, and a contact formed on the source region and the drain region. The contact formed so that an amount of the first insulating film formed on the source region is larger than an amount of the first insulating film formed on the drain region.

A semiconductor device according to another aspect of the present invention is characterized by including a first transistor formed a first gate electrode on a substrate, the first transistor formed a first source region and a first drain region in the substrate, a second transistor a second gate electrode on the substrate, the second transistor formed a second source region and a second drain region in the substrate, a first insulating film formed on the first transistor, the first insulating film configured to generate a stress in a channel region under the first gate electrode. The amount of the first insulating film formed on the first source region is larger than the amount of the first insulating film formed on the first drain region.

A SRAM cell array according to an aspect of the present invention is characterized by including a plurality of SRAM cells including a transfer transistor, a driver transistor, and a load transistor, a first source contact fomed on a source region of the driver transistor, a first drain contact fomed on a drain region of the driver transistor, and a tensile film generating a tensile stress in a channel region of the driver transistor. A distance between the first source contact and a gate electrode of the driver transistor is longer than a distance between the first drain contact and the gate electrode of the driver transistor.

Numerous additional embodiments are also possible. Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF DRAWINGS

Objects and advantages of the invention may become apparent upon reading the following detailed description and upon reference to the accompanying drawings.

FIG. 1 is a cross-sectional view showing a structure of an NMOS transistor of a semiconductor device according to embodiment 1 of the present invention.

FIG. 2 is a cross-sectional view showing a structure of a PMOS transistor of a semiconductor device according to embodiment 2 of the present invention.

FIG. 3 is a plan view showing a structure of an SRAM cell of a semiconductor device according to embodiment 3 of the present invention.

FIG. 4 shows cross-sectional views illustrating the structure of the SRAM cell of the semiconductor device according to embodiment 3 of the present invention, respectively taken along the A-A′ line and the B-B′ line of FIG. 3.

FIG. 5 is another plan view showing the structure of the SRAM cell of the semiconductor device according to embodiment 3 of the present invention.

FIG. 6 is a plan view showing a structure of an SRAM cell of a semiconductor device according to embodiment 4 of the present invention.

FIG. 7 shows cross-sectional views illustrating the structure of the SRAM cell of the semiconductor device according to embodiment 4 of the present invention, respectively taken along the C-C′ line and the D-D′ line of FIG. 5.

FIG. 8 is another plan view showing the structure of the SRAM cell of the semiconductor device according to embodiment 4 of the present invention.

While the invention is subject to various modifications and alternative forms, specific embodiments thereof are shown by way of embodiment in the drawings and the accompanying detailed description. It should be understood that the drawings and detailed description are not intended to limit the invention to the particular embodiments which are described. This disclosure is instead intended to cover all modifications, equivalents and alternatives falling within the scope of the present invention as defined by the appended claims.

### DETAILED DESCRIPTION OF PREFERRED EMBODIMENTS

Descriptions will be provided below for embodiments of the present invention by referring to the drawings.

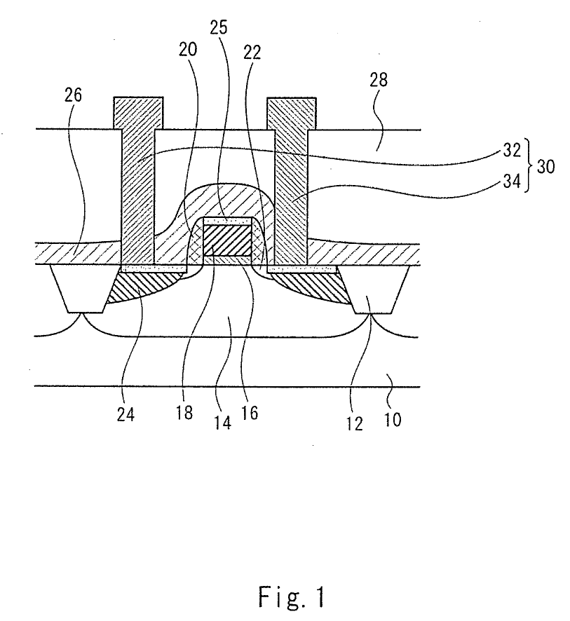

FIG. 1 is a cross-sectional view showing a structure of a semiconductor device according to embodiment 1 of the present invention.

As shown in FIG. 1, an NMOS transistor with an LDD (Lightly Doped Drain) structure is formed in the semiconductor device according to embodiment 1 of the present invention. This transistor includes element dividing regions 12, an element forming region, a p-type well region 14, a gate electrode 18, sidewalls 20, LDD source/drain layers 22, source/drain layers 24. The element dividing regions 12 are formed in the semiconductor substrate 10. The element forming region is defined by these element dividing regions 12. The p-type well region 14 is formed in this element forming region. The gate electrode 18 is formed on the p-type well region 14 with a gate insulating film 16 interposed between the gate electrode 18 and the p-type well region 14. The sidewalls 20 are formed of an insulating film on the two side walls of this gate electrode 18. The LDD source/drain layers 22 are formed in the semiconductor substrate 10 in the both side of the gate electrode 18, and ions of an n-type impurity in low concentration are implanted in the LDD source/drain layers 22. The source/drain layers 24 are formed in the semiconductor substrate 10 in the both side respectively of the sidewalls 20, and are obtained by implanting ions of an n-type impurity in high concentration therein. Silicide 25 is formed on the gate electrode 18 and on the source/drain layers of the n-type.

In addition, a tensile film 26 for generating tensile stress in a channel region is formed over the gate electrode 18 in this NMOS transistor. A TEOS film 28 to serve as an interlayer dielectric is formed on this tensile film 26. If the tensile film 26 is formed in a way that the gate electrode 18 is covered with the tensile film 26 in this manner, this formation makes it possible to generate the tensile stress in the channel region under this gate electrode 18. As a result, this makes it possible to improve mobility of electrons moving in the channel region, and to accordingly improve drain current, that is, current for driving the NMOS transistor.

In addition, contact holes for electrically connecting the source/drain layers 24 to the upper layer of the semiconductor device are formed in this tensile film 26 and the TEOS film 28. A conductor material is embedded in each of the contact holes. Thereby, contacts 30 are formed respectively on the source/drain layers 24. In the case of this embodiment, the contacts 30 are formed in a way that the distance between the source contact 32 and the gate electrode 18 is longer than the distance between the drain contact 34 and the gate electrode 18. As a result, the tensile film 26 is formed in a way that a part of the tensile film 26 remaining on the source and at source side of the gate electrode 18 is larger in amount than another part of the tensile film 26 remaining on the drain and at the drain side of the gate electrode 18, even after the contact holes are formed. In this respect, if the source contact 32 is formed farther away from the gate electrode 18, this formation proportionally increases the amount of the tensile film 26 to remain on the source and at the source side of the gate electrode 18. In other words, the tensile film 26 is formed in a way that, if the source contact 32 is formed farther away from the gate electrode 18, the thickness of the tensile film 26 is larger on the source than on the drain.

In general, improvement of mobility of electrons in the source diffusion layer better serves the purpose of improving drain current in a semiconductor device. Specifically, the improvement of the mobility of electrons in the source diffusion layer serves the purpose better than improvement of electrons in the drain. In the case of this embodiment, the source contact is formed in a way that the distance between the source contact and the gate electrode is larger than the distance between the drain contact and the gate electrode. This formation makes it possible to increase the thickness of the tensile film at the source side of the gate electrode. In other words, the formation makes it possible to make a part of the tensile film at the upper side of the gate electrode on the source larger in amount than another part of the tensile film at the upper side of the gate electrode on the drain. As a result, the mobility of electrons in the source can be improved, and thus the improvement of drain current can be hoped for.

The NMOS transistor which is the thus configured semiconductor device according to embodiment 1 of the present invention is constructed in a way that the distance between the source contact and the gate electrode is longer than the distance between the drain contact and the gate electrode. This construction makes it possible to abate the decrease of the amount of the part of the tensile film on the source by forming the contact holes. In other words, this construction makes it possible to make the tensile film larger in amount at an upper side of the gate electrode on the source than at the other upper side of the gate electrode on the drain. This makes it possible to generate appropriate tensile stress in the channel region from the source by the tensile film. This eventually makes it possible to improve the mobility of electrons in the channel region in the NMOS transistor, and to thus improve drain current, without increasing the area of the NMOS transistor.

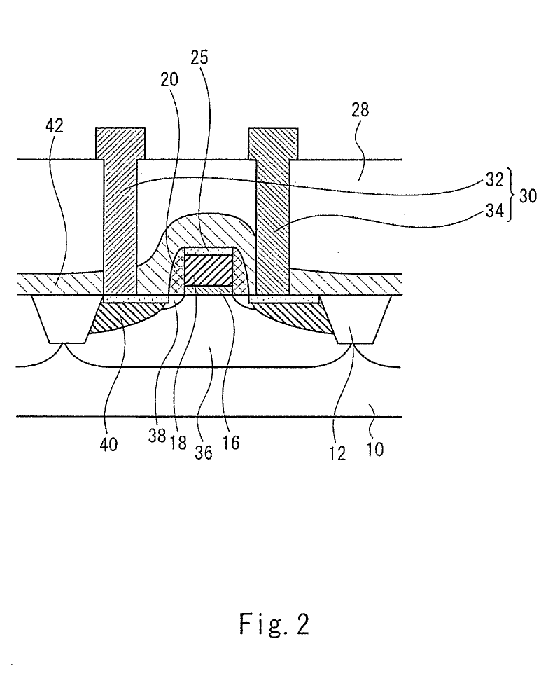

FIG. 2 is a cross-sectional view showing a structure of a semiconductor device according to embodiment 2 of the present invention.

What differentiates embodiment 2 from embodiment 1 of the present invention is that embodiment 2 uses a PMOS transistor instead of the NMOS transistor which is used for embodiment 1. For this reason, as shown in FIG. 2, in embodiment 2, an n-type well 36, p-type LDD source/drain layers 38 and p-type source/drain layers 40 substitute respectively for the p-type well 14, the n-type LDD source/drain layers 22, the n-type source/drain layers 24 which constitute the NMOS transistor of embodiment 1. Incidentally, the other constituent components which are the same as those in embodiment 1 will be denoted by the same reference numerals denoting the same constituent components in embodiment 1, and the descriptions will be omitted for the constituent components.

In addition, in embodiment 2, a compressive film 42 for generating compressive stress in the channel region is formed over the gate electrode 18, and this formation makes it possible to improve mobility of holes in the channel region in the PMOS transistor, and to thus improve drain current in the PMOS transistor, whereas, in embodiment 1, the tensile stress is generated in the channel region by using the tensile film 26 on the side walls of the gate electrode 18.

Furthermore, in this embodiment, the contacts 30 are formed in a way that the distance between the source contact 32 and the gate electrode 18 is longer than the distance between the drain contact 34 and the gate electrode 18, as in the case of embodiment 1. This formation prevents the compressive film 42 on the source from decreasing in amount by forming the contact holes. In other words, this makes it possible to make a part of the compressive film 42 at the upper side of the gate electrode 18 on the source larger in amount than another part of the compressive film 42 at another upper side of the gate electrode 18 on the drain.

The PMOS transistor which is the thus configured semiconductor device according to embodiment 2 of the present invention is constructed in a way that the distance between the source contact and the gate electrode is longer than the distance between the drain contact and the gate electrode. This construction makes it possible to abate the decrease of the amount of the compressive film on the source by forming the contact holes. In other words, this construction makes it possible to make the compression film larger in amount at an upper side of the gate electrode on the source than at the other upper side of the gate electrode on the drain. This makes it possible to generate appropriate compressive stress in the channel region from the source by the compressive film. This eventually makes it possible to improve the mobility of holes in the channel region in the PMOS transistor, and to thus improve drain current, without increasing the area of the PMOS transistor.

The foregoing embodiments have been described by respectively citing the NMOS transistor and the PMOS transistor each with the LDD structure. Embodiments of the present invention are not limited to the NMOS transistor and the PMOS transistor each with the LDD structure. The present invention can be applied to any other NMOS transistor and any other PMOS transistor each with a structure different from the LDD structure, and the present invention is not limited to MOS transistors.

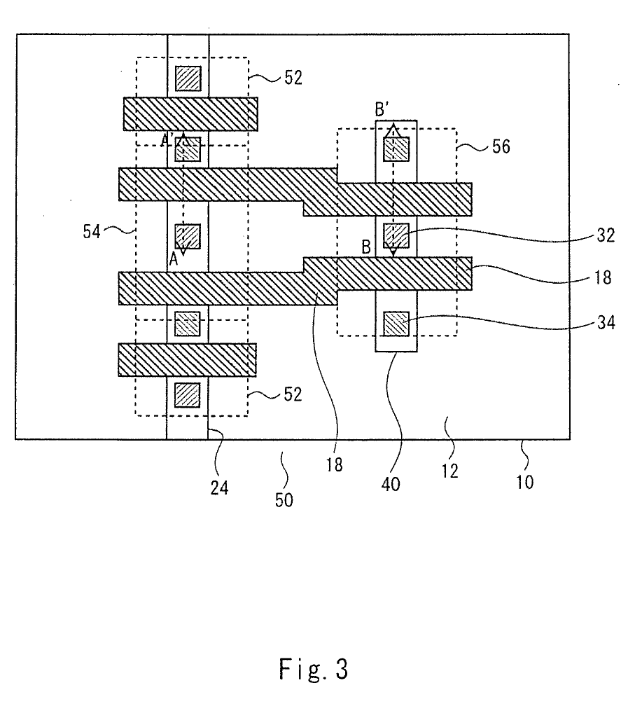

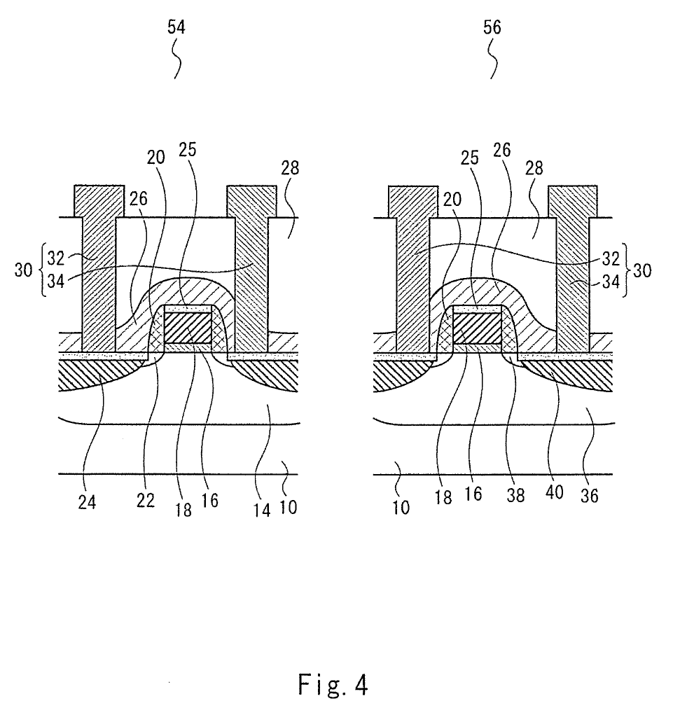

A semiconductor device according to this embodiment is an SRAM cell including the NMOS transistor and the PMOS transistor respectively of the foregoing embodiments. FIG. 3 is a plan view showing a structure of the SRAM cell. FIG. 4 shows cross-sectional views illustrating the structure of the SRAM cell, respectively taken along the A-A′ line and the B-B′ line of FIG. 3. Incidentally, the constituent components which are the same as those in the foregoing embodiments will be denoted by the same reference numerals denoting the same constituent components in the foregoing embodiments, and the descriptions will be omitted for the constituent components.

As shown in FIG. 3, the SRAM cell 50 is configured of two transfer transistors 52, driver transistors 54 and two load transistors 56. Each of the two transfer transistors 52 is constituted of an NMOS transistor. Similarly, each of the two driver transistors 54 is constituted of an NMOS transistor. Each of the two load transistors 56 is constituted of a PMOS transistor.

As shown in FIGS. 3 and 4, each of the NMOS transistors 54, which are the driver transistors, has a structure similar to that of embodiment 1. The NMOS transistors are formed in a way that the distance between the source contact 32 and the gate electrode 18 is longer than the distance between the drain contact 34 and the gate electrode 18. In addition, each of the PMOS transistors 56, which are the load transistors, is formed in a way that the distance between the source contact 32 and the gate electrode 18 is shorter than the distance between the drain contact 34 and the gate electrode 18. Furthermore, in each of the transfer transistors 52, the gate electrode 18 is formed at an approximately central position between the two contacts 30 which are the source contact and the drain contact, as in the case of a usual SRAM cell.

Moreover, the tensile film 26 is formed on the NMOS transistors 54 and the PMOS transistors 56. Specifically, in each of the NMOS transistors 54 which are the driver transistors, the tensile film 26 is formed thicker on the source and at a source side of the gate electrode 18. In each of the PMOS transistors 56 which are the load transistors, the tensile film 26 is formed thicker on the drain and at a drain side of the gate electrode 18. In this respect, the tensile film 26 is formed on the driver transistors 54 and the load transistors 56. It does not matter, however, whether or not the tensile film 26 is formed on the transfer transistors 52. If the tensile film 26 is formed on each of the transfer transistors 52, improvement of drain current can be hoped for because the transfer transistors 52 are NMOS transistors.

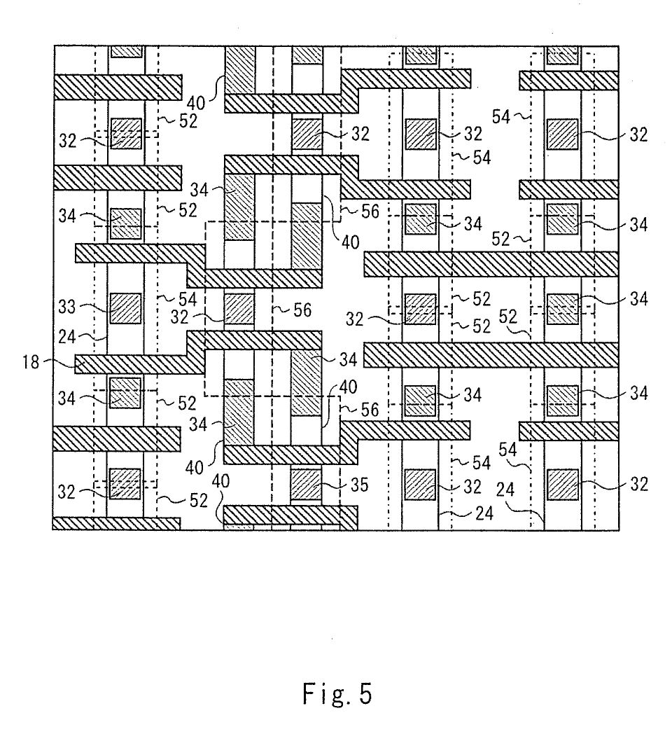

FIG. 5 shows an embodiment of a SRAM cell group in which a plurality of SRAM cells, which have been described, are arrayed. FIG. 5 is a plan view of a structure of one of the SRAM cells.

A plurality of SRAM cells are arrayed on the semiconductor substrate, as shown in FIG. 5. Each of the driver transistors 52 is arranged in a way that the distance between the gate electrode 18 and a corresponding one of the source contacts 32 is longer than the distance between the gate electrode 18 and a corresponding one of the drain contacts 34, as in the case of embodiment 3. In addition, each of the load transistors 56 is arranged in a way that the distance between the gate electrode 18 and a corresponding one of the source contacts 32 is shorter than the distance between the gate electrode 18 and a corresponding one of the drain contacts 34, as in the case of embodiment 3. Furthermore, the tensile film 26 is formed on each of the driver transistors 52 and the load transistors 56. Thereby, drain current in the driver transistors 52 is improved. Configurations of the driver transistors 52 and the load transistors 56 in the thus configured SRAM cell group are the same as those of the driver transistors 52 and the load transistors 56 which are shown in FIG. 4. For this reason, the descriptions will be omitted for the configurations of the driver transistors 52 and the load transistors 56 in the SRAM cell group.

In addition, the SRAM cells are in positions of point symmetry with one another in the array of the SRAM cells. This symmetrical array offers a constitution in which, even if the distance between a gate electrode 18 and its corresponding source contact 32 happens to be longer than the distance between the gate electrode 18 and a corresponding drain contact 34 in a driver transistor 52 in an SRAM cell because of misalignment of the driver transistor, the distance between a gate electrode 18 and its corresponding source contact 32 is shorter than the distance between the gate electrode 18 and a corresponding drain contact 34 in a driver transistor 52 in another SRAM cell which is in a position of point symmetry with the former SRAM cell.

In each of the thus configured SRAM cells according to embodiment 3 of the present invention, contacts are constructed respectively on the source/drain diffusion layers in an NMOS transistor in a way that the distance between the source and the gate electrode is longer than the distance between the drain and the gate electrode. This construction makes it possible to prevent the tensile film from decreasing in amount on the source and at a source side of the gate electrode in the NMOS transistor. In addition, contacts are constructed respectively on the source/drain diffusion layers in a PMOS transistor in a way that the distance between the source and the gate electrode is narrower than the distance between the drain and the gate electrode. This construction makes it possible to decrease the amount of the tensile film on the source and at a source side of the gate electrode in the PMOS transistor. For this reason, tensile stress can be generated in the channel region from the source in the NMOS transistor. This makes it possible to improve mobility of electrons in the channel region, and to thus improve drain current. Furthermore, the tensile film is formed in a smaller amount over the source in the PMOS transistor. This makes it possible to ease the degeneration of characteristics of the PMOS transistor by the tensile film. As a result, characteristics of the NMOS transistor can be improved while preventing the degeneration of the characteristics of the PMOS transistor. This makes it possible to improve performance of the SRAM cell.

The tensile film is used in this embodiment. It does not matter, however, whether or not a compressive film for generating compressive stress in the channel region is used in this embodiment. In a case where the compressive film is used, the contacts respectively on the source and the drain are constructed in the PMOS transistor in a way that, as in the case of embodiment 2, the distance between the source contact and the gate electrode is larger than the distance between the drain contact and the gate electrode, for the purpose of improving drain current in the PMOS transistor. In addition, the contacts are constructed in positions, which ease the degeneration of the performance of the NMOS transistor, in the NMOS transistor in a way that, as in the case of embodiment 2, the distance between the source contact and the gate electrode is narrower than the distance between the drain contact and the gate electrode, for the same purpose.

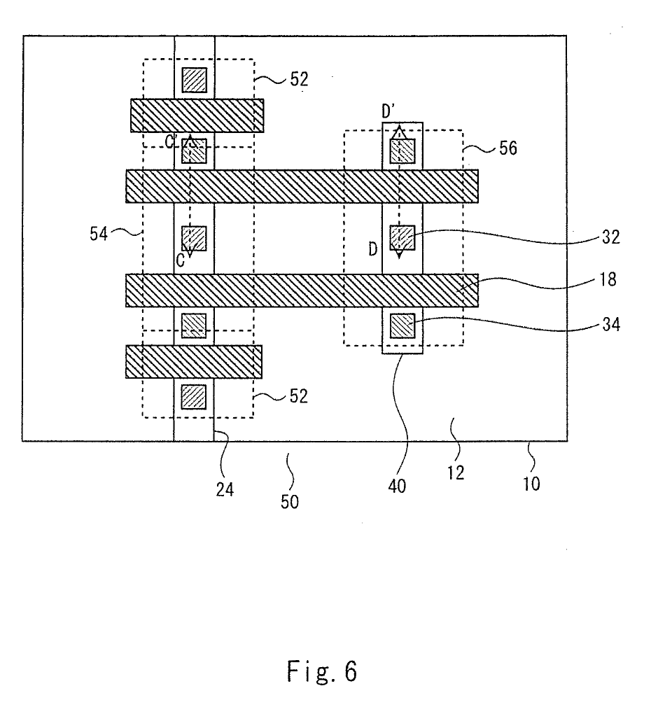

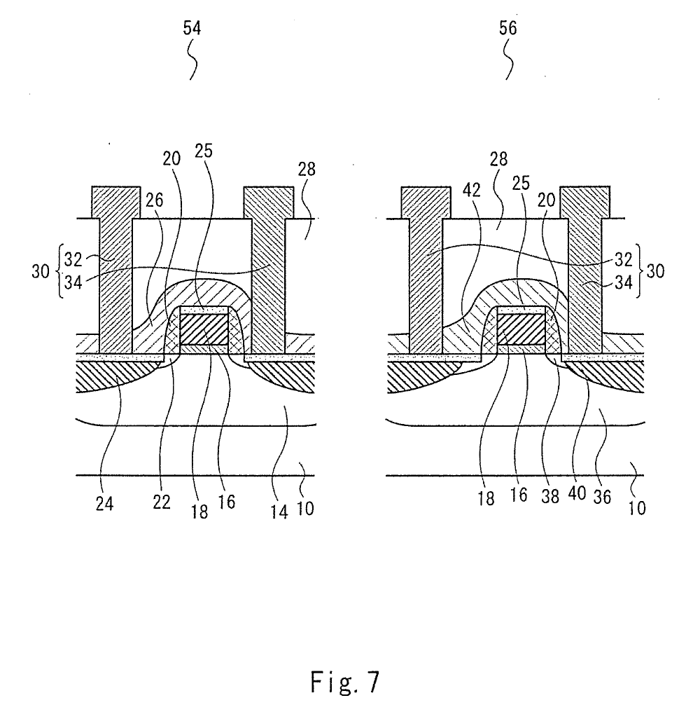

FIG. 6 is a plan view showing a structure of an SRAM cell in a semiconductor device according to embodiment 4 of the present invention. FIG. 7 shows cross-sectional views of the structure of the SRAM cell in the semiconductor device according to embodiment 4 of the present invention, respectively taken along the C-C′ line and the D-D′ line of FIG. 6. Incidentally, the constituent components which are the same as those in the foregoing embodiments will be denoted by the same reference numerals denoting the same constituent components in the foregoing embodiments, and the descriptions will be omitted for the constituent components.

What differentiates embodiment 4 from embodiment 3 of the present invention is that, in this embodiment, each of the SRAM cells 50 is configured by use of an insulating film for improving drain current in a corresponding one of MOS transistors as shown in FIGS. 5 and 6, whereas, in embodiment 3, the tensile films each for generating tensile stress are used for the respective channel regions. Specifically, the tensile film 26 is formed on the NMOS transistors 54 which are the driver transistors, and the compressive film 42 is formed on the PMOS transistors 56 which are the load transistors. In addition, contacts 30 in each of the MOS transistors are constructed in a way that, as in the case of the foregoing embodiments, the distance between the source contact 32 and the gate electrode 18 is longer than the distance between the drain contact 34 and the gate electrode 18, for the purpose of improving drain current in the MOS transistor. In this respect, in each of the transfer transistors 52, the gate electrode is formed in an approximately central position between the contacts which are the source contact and the drain contact. In addition, the tensile film 26 and the compressive film 42 are formed respectively on a corresponding one of the driver transistors 54 and a corresponding one of the load transistors 56. It does not matter, however, whether the tensile film 26 or the compressive film 42 is formed on each of the transfer transistors 52. Moreover, it does not matter that the insulating film, which generated a stress in a channel region, is not formed on each of the transfer transistors. If the tensile film 26 is formed on each of the transfer transistors 52, improvement of drain current can be hoped for because the transfer transistors are the NMOS transistors.

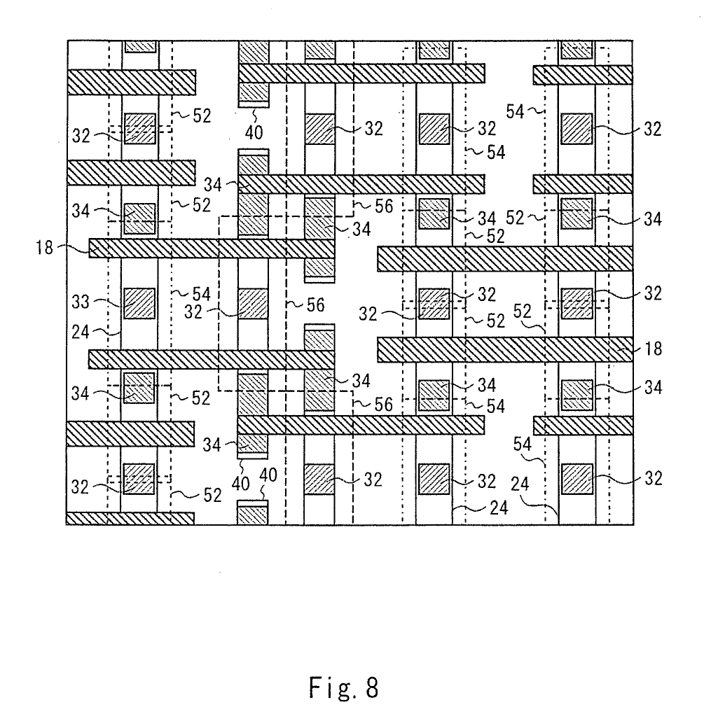

FIG. 8 shows an embodiment of an SRAM cell group in which a plurality of SRAM cells, which have been described, are arrayed. FIG. 8 is a plan view showing a structure of one of the SRAM cells.

A plurality of SRAM cells are arrayed on the semiconductor substrate, as shown in FIG. 8. Each of the driver transistors 52 is arranged in a way that the distance between the gate electrode 18 and a corresponding one of the source contacts 32 is longer than the distance between the gate electrode 18 and a corresponding one of the drain contacts 34, as in the case of embodiment 4. Each of the load transistors 56 is also arranged in a way that the distance between the gate electrode 18 and a corresponding one of the source contacts 32 is longer than the distance between the gate electrode 18 and a corresponding one of the drain contacts 34, as in the case of embodiment 4. Furthermore, the tensile film 26 is formed on each of the driver transistors 52, and the compressive film 42 is formed on each of the load transistors 56. Thereby, drain current in the driver transistors 52 and the load transistors 56 are improved. Configurations of the driver transistors 52 and the load transistors 56 in the thus configured SRAM cell group are the same as those of the driver transistors 52 and the load transistors 56 which are shown in FIG. 7. For this reason, the descriptions will be omitted for the configurations of the driver transistors 52 and the load transistors 56 in the SRAM cell group.

In addition, the SRAM cells are in positions of point symmetry with one another in the array of the SRAM cells. This symmetrical array offers a constitution in which, even if the distance between a gate electrode 18 and its corresponding source contact 32 happens to be longer than the distance between the gate electrode 18 and a corresponding drain contact 34 in a driver transistor 52 in an SRAM cell because of misalignment of the driver transistor, the distance between a gate electrode 18 and its corresponding source contact 32 is shorter than the distance between the gate electrode 18 and a corresponding drain contact 34 in a driver transistor 52 in another SRAM cell which is in a position of point symmetry with the former SRAM cell.

In each of the thus configured SRAM cells, contacts are constructed respectively on the source/drain diffusion layers in each of the load transistors and the driver transistors constituting the SRAM cell in a way that the distance between the source contact and the gate electrode is longer than the distance between the drain contact and the gate electrode. This construction makes it possible to prevent decrease of the amount of the insulating film on the source by forming the contact holes. In other words, the construction of the contacts in such a manner makes it possible to make the tensile film larger in amount at the upper side of the gate electrode on the source than at the upper side of the gate electrode on the drain in each of the driver transistors, and to make the compressive film larger in amount at the upper side of the gate electrode than at the upper side of the gate electrode on the drain in each of the load transistors. This makes it possible to improve drain current in the NMOS transistors and the PMOS transistors constituting each of the SRAM cells, and to thus improve the performance of each of the SRAM cells better in this embodiment than in embodiment 3.

The foregoing embodiments have been described by respectively citing the embodiments of the present invention to MOS transistors. However, the present invention can be applied to transistors of any other types. In addition, embodiments 3 and 4 have been described by citing the embodiments of the present invention to SRAM cells. However, the present invention can be applied to a semiconductor device which includes NMOS transistors of any other type and PMOS transistors of any other type.

Other embodiment of this invention will be apparent to those skilled in the art from consideration of the specification and practice of the invention disclosed herein. It is intended that the specification and embodiment be considered as exemplary only, with a true scope and spirit of the invention being indicated by the following.

What is claimed is:

1. A semiconductor device, comprising:
a substrate;
a gate electrode formed on the substrate;
a source region and a drain region formed in the substrate, the source region formed on a first side of the gate electrode and the drain region formed on a second side of the gate electrode, the first side opposite the second side;
a first insulating film formed on the substrate, the first insulating film configured to generate a stress in a channel region under the gate electrode; and
a first contact formed on the source region and a second contact formed on the drain region, wherein a first amount of the first insulating film formed on the source region is greater than a second amount of the first insulating film formed on the drain region.

2. The semiconductor device according to claim 1, wherein the source region and the drain region is n-type, and the first insulating film is configured to generate a tensile stress in a channel region under the gate electrode.

3. The semiconductor device according to claim 1, wherein the source region and the drain region are p-type, and the first insulating film is configured to generate a compressive stress in a channel region under the gate electrode.

4. The semiconductor device according to claim 2, wherein a first distance between the gate electrode and the first contact formed on the source region is greater than a second distance between the gate electrode and the second contact formed on the drain region.

5. The semiconductor device according to claim 3, wherein a first distance between the gate electrode and the first contact formed on the source region is greater than a second distance between the gate electrode and the second contact formed on the drain region.

6. The semiconductor device according to claim 1, wherein the first insulating film includes SiN.

7. A semiconductor device, comprising:
a first transistor having a first gate electrode formed on a substrate, a first source region in the substrate and a first drain region in the substrate;
a second transistor having a second gate electrode formed on the substrate, a second source region formed in the substrate and a second drain region in the substrate; and
a first insulating film formed on the first transistor, the first insulating film configured to generate a stress in a first channel region under the first gate electrode, wherein a first amount of the first insulating film formed on the first source region is greater than a second amount of the first insulating film formed on the first drain region.

8. The semiconductor device according to claim 7, further comprising a first source contact formed on the first source region, and a first drain contact formed on the first drain region, wherein a first distance between the first electrode and the first source contact is greater than a second distance between the first electrode and the first drain contact.

9. The semiconductor device according to claim 8, wherein the first transistor is n-type transistor and the first insulating film is configured to generate a tensile stress in the first channel region under the first gate electrode.

10. The semiconductor device according to claim 9, further comprising a second source contact formed on the second source region, and a second drain contact formed on the second drain region, wherein a third distance between the second gate electrode and the second drain contact is greater than a fourth distance between the second gate electrode and the second source contact.

11. The semiconductor device according to claim 10, wherein the second transistor is a p-type transistor and the first insulating film is formed on the second transistor.

12. The semiconductor device according to claim 8, wherein the first transistor is a p-type transistor and wherein the first insulating film is configured to generate a compressive stress in the first channel region under the first gate electrode.

13. The semiconductor device according to claim 12, further comprising a second source contact formed on the second source region, and a second drain contact formed on the second drain region, wherein a third distance between the second gate electrode and the second drain contact is greater than a fourth distance between the second gate electrode and the second source contact.

14. The semiconductor device according to claim 13, wherein the second transistor is an n-type transistor and the first insulating film is formed on the second transistor.

15. The semiconductor device according to claim 9, further comprising
a second insulating film formed on the second transistor, wherein the second insulating film is configured to generate a compressive stress in a second channel region under the second gate electrode and the second transistor is p-type transistor;
a second source contact formed on the second source region; and
a second drain contact formed on the second drain region, wherein a third distance between the second gate electrode and the second source contact is greater than a fourth distance between the second gate electrode and the second drain contact.

16. An SRAM cell array, comprising:
a plurality of SRAM cells including a transfer transistor, a driver transistor, and a load transistor;
a first source contact formed on a source region of the driver transistor;
a first drain contact formed on a drain region of the driver transistor; and
a tensile film configured to generate a tensile stress in a channel region of the driver transistor, wherein a first distance between the first source contact and a gate electrode of the driver transistor is greater than a second distance between the first drain contact and the gate electrode of the driver transistor.

17. The SRAM cell array according to claim 16, further comprising,
a second source contact formed on a source region of the load transistor;
a second drain contact formed on a drain region of the load transistor; and
a compressive film configured to generate a compressive stress in a channel region of the load transistor, wherein a third distance between the second drain contact and a gate electrode of the load transistor is greater than a fourth distance between the second drain contact and the gate electrode of the load transistor.

18. The SRAM cell array according to claim 16, further comprising,
a second source contact formed on a source region of the load transistor; and
a second drain contact formed on a drain region of the load transistor, wherein the tensile film is formed on the load transistor and a third distance between the second drain contact and a gate electrode of the load transistor is less than a fourth distance between the second drain contact and the gate electrode of the load transistor.

19. The SRAM cell array according to claim 16, wherein at least a first SRAM cell in the SRAM cell array is point symmetrical with a second SRAM cell in the SRAM cell array.

20. The SRAM cell array according to claim 16, wherein the driver transistor is an n-type transistor and the load transistor is a p-type transistor.

21. A method for manufacturing a semiconductor device, comprising:
forming a gate electrode on a substrate;
forming a source region and a drain region in the substrate, the source region formed on a first side of the gate electrode and the drain region formed on a second side of the gate electrode, the first side opposite the second side;
forming a first contact on the source region at a first distance from the gate electrode;
forming a second contact on the drain region at a second distance from the gate electrode; and
forming a first insulating film on the substrate, wherein the first insulating film is configured to generate stress in a channel region under the gate electrode on the substrate and a first amount of the first insulating film formed on the source region is greater than a second amount of the first insulating film formed on the drain region.

22. The method according to claim 21, wherein the first distance is greater than the second distance.

23. The method according to claim 22, wherein the second distance is greater than the first distance.

24. A method for manufacturing a semiconductor device, comprising:
forming a first transistor, the first transistor having a first gate electrode formed on a substrate, a first source region formed in the substrate and a first drain region formed in the substrate;
forming a second transistor, the second transistor having a second gate electrode formed on the substrate, a second source region formed in the substrate and a second drain region formed in the substrate; and
forming a first insulating film on the first transistor, the first insulating film configured to generate a stress in a first channel region under the first gate electrode, wherein a first amount of the first insulating film formed on the first source region is greater than a second amount of the first insulating film formed on the first drain region.

25. The method according to claim 24, further comprising
forming a first source contact on the first source region at a first distance from the first electrode; and
forming a first drain contact on the first drain region at a second distance from the first electrode, wherein the first distance is greater than the second distance.

26. The method according to claim 25, further comprising forming a second insulating film on the second transistor, the second insulating film configured to generate a stress in a second channel region under the second gate electrode, wherein a third amount of the second insulating film formed on the second drain region is greater than a fourth amount of the first insulating film formed on the second source region.

27. The method according to claim 26, further comprising
forming a second source contact on the second source region at a third distance from the second gate electrode; and
forming a second drain contact on the second drain region at a fourth distance from the second gate electrode, wherein the fourth distance is greater than the third distance.

28. The method according to claim 27, further comprising forming a second insulating film the second insulating film configured to generate a stress in a second channel region under the second gate electrode.

29. The method according to claim 28, wherein the first transistor is n-type transistor, the first insulating film is configured to generate a tensile stress in the first channel region under the first gate electrode, the second transistor is p-type transistor and the second insulating film is configured to generate a compressive stress in the second channel region under the second gate electrode.

30. The method according to claim 29, wherein the first transistor is p-type transistor, the first insulating film is configured to generate a compressive stress in the first channel region under the first gate electrode, the second transistor is n-type transistor and the second insulating film is configured to generate a tensile stress in the second channel region under the second gate electrode.

31. A method for manufacturing an SRAM cell array, comprising:
forming a plurality of SRAM cells, each SRAM cell including a transfer transistor, a driver transistor, and a load transistor, wherein forming each of the SRAM cells comprises:
forming a first source contact on a source region of the driver transistor at a frist distance from a gate electrode of the driver transistor;
forming a first drain contact on a drain region of the driver transistor at a second distance from the gate electrode of the driver transitor, the first distance greater than the second distance; and
forming a tensile film in a channel region of the driver transistor, the tensile film configured to generate a tensile stress in the channel region of the driver transistor.

32. The method according to claim 31, further comprising,
forming a second source contact on a source region of the load transistor at a third distance from a gate electrode of the load transistor;
forming a second drain contact on a drain region of the load transistor at a fourth distance from the gate electrode of the load transistor, the fourth distance greater than the third distance; and
forming a compressive film in a channel region of the load transistor, the compressive film configured to generate a compressive stress in a channel region of the load transistor.

33. The method according to claim 32, wherein at least a first SRAM cell in the SRAM cell array is point symmetrical with a second SRAM cell in the SRAM cell array.
